(19) United States
(12) Patent Application Publication
(10) Pub. No.: US 2009/0286355 A1
(43) Pub. Date: Nov. 19, 2009

(54) FLIP-CHIP PROCESS BY PHOTO-CURING ADHESIVE

(75) Inventor: Chung-Mao YEH, Taichung City (TW)

Correspondence Address: BROWDY AND NEIMARK, P.L.L.C.;624 NINTH STREET, NW, SUITE 300, WASHINGTON, DC, 20001-5303, US

(73) Assignee: LINGSEN PRECISION INDUSTRIES, LTD., Taichung (TW)

(21) Appl. No.: 12/264,474

(22) Filed: Nov. 4, 2008

(30) Foreign Application Priority Data
May 16, 2008 (TW) 97118218

(51) Int. Cl. H01L 21/50

(52) U.S. Cl. 438/108; 257/E21.499

(57) ABSTRACT

A flip-chip process includes the steps of disposing a plurality of spherical contact members on a surface of a wafer; forming a photo-curing adhesive layer on the surface of the wafer, wherein said photo-curing adhesive layer covers a part of each of the spherical contact members to expose the spherical contact members of the photo-curing adhesive layer; solidifying the photo-curing adhesive layer by exposure; cutting the wafer into a plurality of chip units; placing the chip units on a substrate to let the spherical contact members lie against contact points of the substrate; and pressurizing the chip units and then heating the spherical contact potions to enable the spherical contact members to be welded and electrically connected with the chip units and the contact points of the substrate

### BACKGROUND OF THE INVENTION

1. Field of the Invention

The present invention relates generally to semiconductor, and more particularly, to a flip-chip process by photo-curing adhesive.

2. Description of the Related Art

A conventional flip-chip process is to carry a chip on a substrate. However, the coefficient of thermal expansion (15 ppm/° C.) of the substrate is different from that (2.5 ppm/° C.) of the chip, what is between the substrate and the chip is subject to shear failure to have fatigue crack and imperfect contact.

Referring to FIG. 8, to solve the aforementioned problems, a packaging material is filled between a substrate 1 and a chip 2 and then solidified by heating to be a spacer 3 for enhanced mechanical strength of the overall structure. However, a plurality of spherical contact members 4 located between the substrate 1 and the chip 2 are arranged in ball grid array (BGA), and it is not easy to drain the air from what is between the substrate 1 and the chip during the process that the packaging material is filled, such that a number of air bubbles 5 are formed in the spacer 3. In other words, the air bubbles 5 while heated during the heating process is still subject to expansion to cause and apply the shear failure to the spacer 3 and the spherical contact members 4, such that such structure is still defective for the fatigue crack and the imperfect contact. In addition, the heat energy generated while the chip 2 is being operated may result in the air bubbles 5 to incur the aforesaid problems.

### SUMMARY OF THE INVENTION

The primary objective of the present invention is to provide a flip-chip process by photo-curing adhesive, wherein the flip-chip process definitely improves the drawbacks of the prior art, avoiding formation of air bubbles, and increases the yield of production.

The foregoing objective of the present invention is attained by the flip-chip process including the steps of disposing a plurality of spherical contact members on a surface of a wafer; forming a photo-curing adhesive layer on the surface of the wafer, wherein said photo-curing adhesive layer covers a part of each of the spherical contact members to expose the spherical contact members of the photo-curing adhesive layer; solidifying the photo-curing adhesive layer by exposure; cutting the wafer into a plurality of chip units; placing the chip units on a substrate to let the spherical contact members lie against contact points of the substrate; and pressurizing the chip units and then heating the spherical contact potions to enable the spherical contact members to be welded and electrically connected with the chip units and the contact points of the substrate.

### BRIEF DESCRIPTION OF THE DRAWINGS

FIG. 1 is a flow chart of a preferred embodiment of the present invention.

FIG. 2 is a top view of the wafer of the preferred embodiment of the present invention, showing the arrangement of the spherical contact members.

FIG. 3 is a schematic view of the wafer of the preferred embodiment of the present invention, showing the structure of the wafer and the spherical contact members.

FIG. 4 is another schematic view of the preferred embodiment of the present invention, showing the structure of the photo-curing adhesive layer.

FIG. 5 is a schematic view of the preferred embodiment of the present invention, illustrating that the photo-curing adhesive layer is treated by exposure.

FIG. 6 is another schematic view of the preferred embodiment of the present invention, illustrating that the chip units lie against the substrate.

FIG. 7 is another schematic view of the preferred embodiment of the present invention, illustrating that the chip units are pressurized and the spherical contact members are heated.

FIG. 8 is a schematic view of the structure based on the prior art, showing that the air bubbles are formed in the packing material.

### DETAILED DESCRIPTION OF PREFERRED EMBODIMENTS

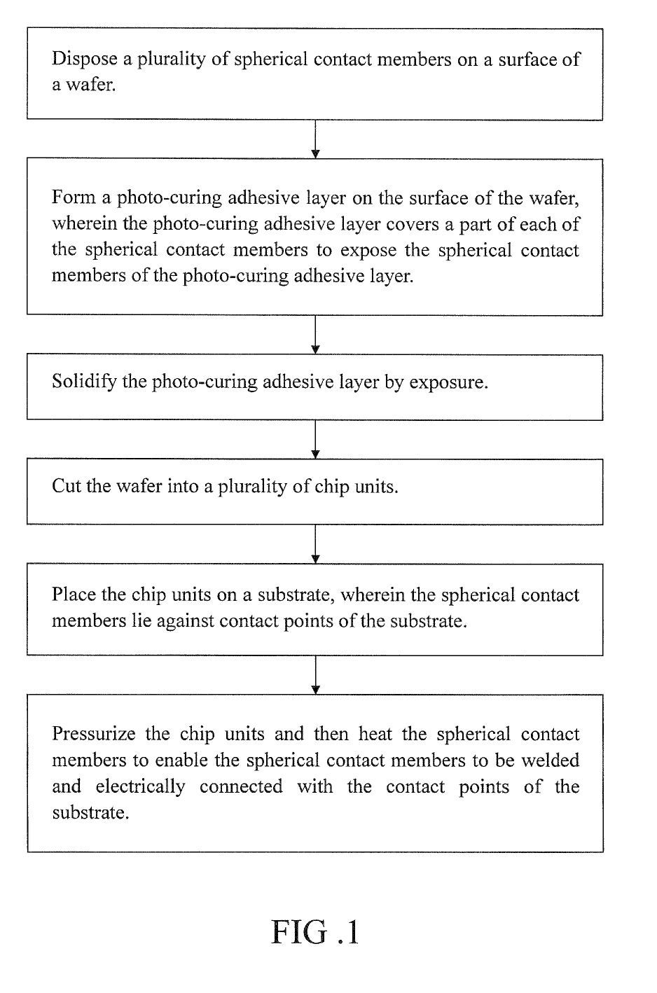

Referring to FIGS. 1-7, a flip-chip process by photo-curing adhesive in accordance with a preferred embodiment of the present invention includes the following steps.

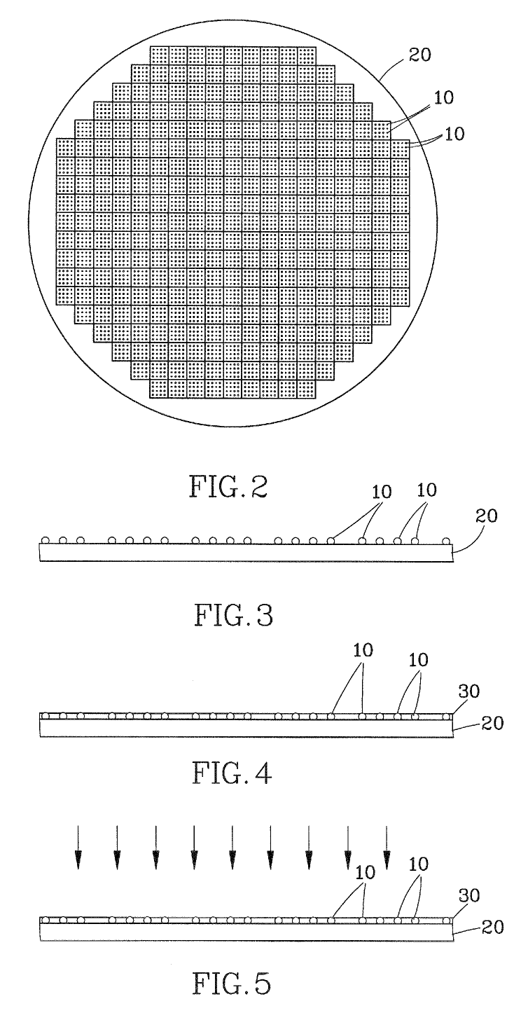

a) Dispose a plurality of spherical contact members 10 on a top side of a wafer 20, as shown in FIGS. 2 and 3.

b) Form a photo-curing adhesive layer 30 on a top side of the wafer 20 by spin coating, as shown in FIG. 4. The spin coating is taken for the purpose of preventing air bubbles from generation during formation of the photo-curing adhesive layer 30. The photo-curing adhesive layer 30 covers a part of each of the spherical contact members 10, covering at least 50% of the surface area of each of the spherical contact members 10, whereby each of the spherical contact members 10 is exposed of the photo-curing adhesive layer 30. In this embodiment, the photo-curing adhesive layer 30 covers 70% of the surface area of each of the spherical contact members 10.

c) Expose the photo-curing adhesive layer 30 by ultraviolet rays to solidify and attach the photo-curing adhesive layer 30 to the top side of the wafer 20.

d) Cut the wafer 20 into a plurality of chip units 22.

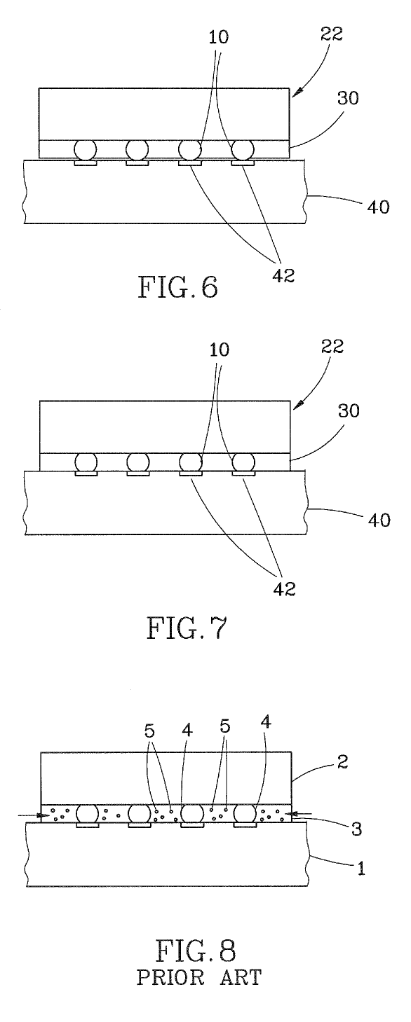

e) Put the chip units 22 on a top side of a substrate 40 having a plurality of contact points 42, as shown in FIG. 6, wherein the spherical contact members 10 lie against the contact points 42 of the substrate 40.

f) Pressurize the chip units 22 and then heat the spherical contact members 10, as shown in FIG. 7, to enable the spherical contact members 10 to be welded and electrically connected with the chip units 22 and the contact points 42 of the substrate 40.

In conclusion, the present invention can definitely improve the drawbacks of the prior art, preventing the air bubbles from generation between the chip units and the substate 40 and preventing the photo-curing adhesive layer 30 and the spherical contact members 10 from the shear failure to further overcome the fatigue crack and the imperfect contact. Compared with the prior art, the present invention causes better yield of production, and the photo-curing adhesive layer of the present invention can provide better rigidity and adherence to cause better overall structural mechanical strength.

Although the present invention has been described with respect to a specific preferred embodiment thereof, it is no way limited to the details of the illustrated structures but changes and modifications may be made within the scope of the appended claims.

What is claimed is:

1. A flip-chip process by photo-curing adhesive layer, comprising steps of:
a) disposing a plurality of spherical contact members on a surface of a wafer;
b) forming a photo-curing adhesive layer on the surface of said wafer, wherein said photo-curing adhesive layer covers a part of each of said spherical contact members to expose said spherical contact members of said photo-curing adhesive layer;
c) solidifying said photo-curing adhesive layer by exposure;
d) cutting said wafer into a plurality of chip units;
e) placing said chip units on a substrate, wherein said spherical contact members lie against contact points of said substrate; and
f) pressurizing said chip units and then heating said spherical contact members to enable said spherical contact members to be welded and electrically connected with said contact points of said substrate.

2. The flip-chip process as defined in claim 1, wherein said photo-curing adhesive layer in the step b) covers at least 50% of the surface area of each of said spherical contact members.

3. The flip-chip process as defined in claim 1, wherein said photo-curing adhesive layer in the step b) is formed by spin coating.
